(19) United States
(12) Patent Application Publication
(10) Pub. No.: US 2025/0125783 A1
(43) Pub. Date: Apr. 17, 2025

(54) TRANSVERSELY-EXCITED FILM BULK ACOUSTIC RESONATORS WITH ELECTRODES HAVING A SECOND LAYER OF VARIABLE WIDTH

(71) Applicant: Murata Manufacturing Co., Ltd., Nagaokakyo-shi (JP)

(72) Inventors: Viktor PLESSKI, Gorgier (CH); Julius KOSKELA, Helsinki (FI)

(21) Appl. No.: 18/989,375

(22) Filed: Dec. 20, 2024

Related U.S. Application Data
(63) Continuation of application No. 18/498,887, filed on Oct. 31, 2023.
Application No. 18/498,887 is a continuation of application No. 17/172,692, filed on Feb. 10, 2021, now Pat. No. 11,855,602.
Application No. 17/172,692 is a continuation of application No. 17/094,133, filed on Nov. 10, 2020, now Pat. No. 10,992,282.
(60) Provisional application No. 63/041,052, filed on Jun. 18, 2020.

(51) Int. Cl. H03H 9/02; H03H 9/205; H03H 9/56

(52) U.S. Cl. CPC H03H 9/02157; H03H 9/02015; H03H 9/02228; H03H 9/205; H03H 9/568

(57) ABSTRACT

An acoustic resonator device is provided that includes a piezoelectric layer; and an interdigital transducer (IDT) at a surface of the piezoelectric layer, the IDT comprising interleaved fingers. At least one interleaved finger of the interleaved fingers comprises a first layer and a second layer over the first layer, wherein the first layer is between the piezoelectric layer and the second layer. Moreover, a shape of the second layer varies with respect to at least one other interleaved finger of the interleaved fingers. A thickness of the first layer is less than a thickness of the second layer.

### CROSS REFERENCE TO RELATED APPLICATIONS

This patent application is a continuation of U.S. application Ser. No. 18/498,887, filed Oct. 31, 2023, which is a continuation of U.S. application Ser. No. 17/172,692, filed Feb. 10, 2021, now issued as U.S. Pat. No. 11,855,602, which is a continuation of U.S. application Ser. No. 17/094,133, filed Nov. 10, 2020, now issued as U.S. Pat. No. 10,992,282, which claims priority from U.S. Provisional Patent Application No. 63/041,052, filed Jun. 18, 2020, entitled XBAR WITH REDUCED LEVELS OF SPURIOUS MODE. Each of these applications is incorporated herein by reference in their entireties.

### TECHNICAL FIELD

This disclosure relates to radio frequency filters using acoustic wave resonators, and specifically to bandpass filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the specific application. For example, a “pass-band” may be defined as a frequency range where the insertion loss of a filter is less than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies proposed for future communications networks.

The desire for wider communication channel bandwidths will inevitably lead to the use of higher frequency communications bands. Radio access technology for mobile telephone networks has been standardized by the 3GPP (3rd Generation Partnership Project). Radio access technology for 5^{th} generation mobile networks is defined in the 5G NR (new radio) standard. The 5G NR standard defines several new communications bands. Two of these new communications bands are n77, which uses the frequency range from 3300 MHz to 4200 MHZ, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77 and n79 must be capable of handling the transmit power of the communications device. WiFi bands at 5 GHz and 6 GHz also require high frequency and wide bandwidth. The 5G NR standard also defines millimeter wave communication bands with frequencies between 24.25 GHz and 40 GHz.

### BRIEF DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3A is an alternative schematic cross-sectional view of the XBAR of FIG. 1.

FIG. 3B is another alternative schematic cross-sectional view of the XBAR of FIG. 1.

FIG. 3C is an alternative schematic plan view of an XBAR

FIG. 4 is a graphic illustrating a primary acoustic mode in an XBAR.

FIG. 5 is a schematic circuit diagram of a band-pass filter using acoustic resonators in a ladder circuit.

FIG. 6 is a cross-sectional view and two detailed cross-sectional views of a portion of an XBAR with two-layer interdigital transducer (IDT) fingers.

FIG. 7A is a plan view of a two-layer IDT finger with an upper layer extending along a length of the finger in a trapezoidal shape.

FIG. 7B is a plan view of a two-layer IDT finger with an upper layer extending along a length of the finger in an hourglass shape.

FIG. 7C is a plan view of a two-layer IDT finger with an upper layer extending along a length of the finger in a notched shape.

FIG. 7D is a plan view of a two-layer IDT finger with an upper layer extending along a length of the finger in another trapezoidal shape.

FIG. 7E is a plan view of a two-layer IDT finger with an upper layer extending along a length of the finger in a half hourglass shape.

FIG. 7F is a plan view of a two-layer IDT finger with an upper layer extending along a length of the finger in an elongated hexagonal shape.

FIG. 7G is a plan view of a two-layer IDT finger with an upper layer extending along a length of the finger in an irregular shape.

FIG. 8 is a plan chart of a process for fabricating an XBAR or a filter including XBARs.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

### Description of Apparatus

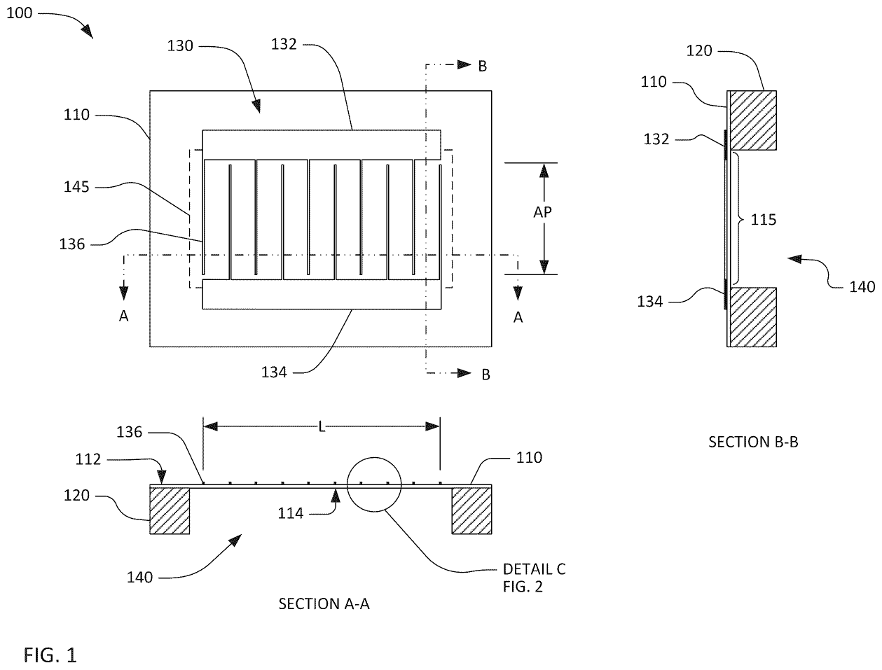

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the front and back surfaces 112, 114. However, XBARs may be fabricated on piezoelectric plates with other crystallographic orientations.

The back surface 114 of the piezoelectric plate 110 is attached to a surface of the substrate 120 except for a portion of the piezoelectric plate 110 that forms a diaphragm 115 spanning a cavity 140 formed in the substrate. The portion of the piezoelectric plate that spans the cavity is referred to herein as the “diaphragm” 115 due to its physical resemblance to the diaphragm of a microphone. As shown in FIG. 1, the diaphragm 115 is contiguous with the rest of the piezoelectric plate 110 around all of a perimeter 145 of the cavity 140. In this context, “contiguous” means “continuously connected without any intervening item”. In other configurations, the diaphragm 115 may be contiguous with the piezoelectric plate around at least 50% of the perimeter 145 of the cavity 140.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers (not shown in FIG. 1).

“Cavity” has its conventional meaning of “an empty space within a solid body.” The cavity 140 may be a hole completely through the substrate 120 (as shown in Section A-A and Section B-B) or a recess in the substrate 120 under the diaphragm 115. The cavity 140 may be formed, for example, by selective etching of the substrate 120 before or after the piezoelectric plate 110 and the substrate 120 are attached.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. As will be discussed in further detail, the primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the portion 115 of the piezoelectric plate that spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds of parallel fingers in the IDT 110. Similarly, the thickness of the fingers in the cross-sectional views is greatly exaggerated.

The dimensions of an XBAR scale inversely with frequency. For example, the resonance frequency of an XBAR can be reduced by 20% by increasing all of the dimensions of an XBAR by 20%. Since the resonance frequency of an XBAR is primarily determined by the thickness of the piezoelectric plate, it is convenient to express others dimensions relative to the piezoelectric plate thickness.

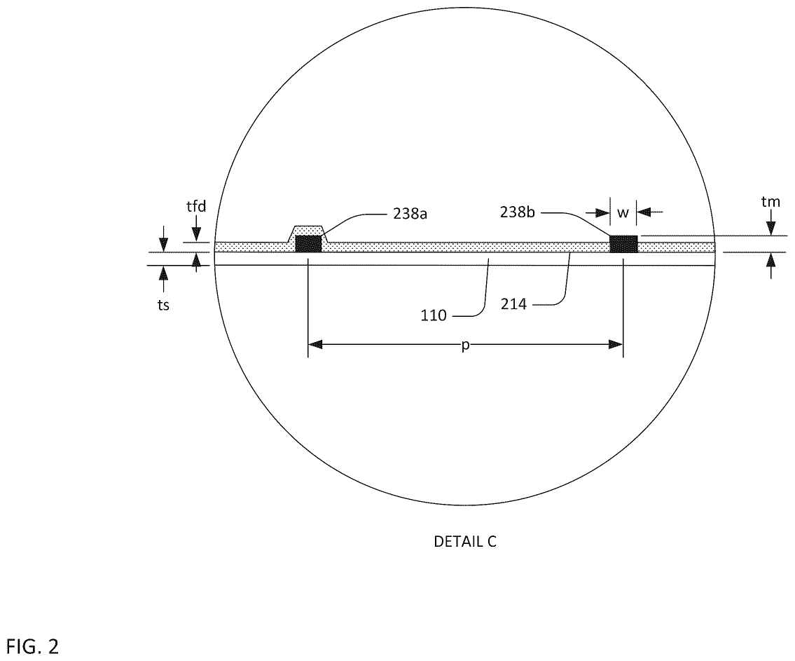

FIG. 2 shows a detailed schematic cross-sectional view of the XBAR 100. The piezoelectric plate 110 is a single-crystal layer of piezoelectrical material having a thickness ts. Thickness ts may be, for example, 100 nm to 1500 nm. When used in filters for LTE™ bands from 3.4 GHz to 6 GHz (e.g. bands 42, 43, 46), the thickness ts may be, for example, 200 nm to 1000 nm.

A front-side dielectric layer 214 may optionally be formed on the front side of the piezoelectric plate 110. The “front side” of the XBAR is, by definition, the surface facing away from the substrate. The front-side dielectric layer 214 has a thickness tfd. The front-side dielectric layer 214 may be formed only between the IDT fingers (e.g. IDT finger 238b) or may be deposited as a blanket layer such that the dielectric layer is formed both between and over the IDT fingers (e.g. IDT finger 238a). The front-side dielectric layer 214 may be a non-piezoelectric dielectric material, such as silicon dioxide or silicon nitride. tfd may be, for example, 0 to 500 nm. tfd is typically less than the thickness ts of the piezoelectric plate. The front-side dielectric layer 214 may be formed of multiple layers of two or more materials.

The IDT fingers 238a and 238b may be aluminum, an aluminum alloy, copper, a copper alloy, beryllium, gold, tungsten, molybdenum or some other conductive material. The IDT fingers are considered to be “substantially aluminum” if they are formed from aluminum or an alloy comprising at least 50% aluminum. The IDT fingers are considered to be “substantially copper” if they are formed from copper or an alloy comprising at least 50% copper. The IDT fingers are considered to be “substantially molybdenum” if they are formed from molybdenum or an alloy comprising at least 50% molybdenum. Thin (relative to the total thickness of the conductors) layers of other metals, such as chromium or titanium, may be formed under and/or over and/or as layers within the fingers to improve adhesion between the fingers and the piezoelectric plate 110 and/or to passivate or encapsulate the fingers and/or to improve power handling. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The geometry of the IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e. the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric slab 212. The width of the IDT fingers in an XBAR is not constrained to be near one-fourth of the acoustic wavelength at resonance. For example, the width of XBAR IDT fingers may be 500 nm or greater, such that the IDT can be readily fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

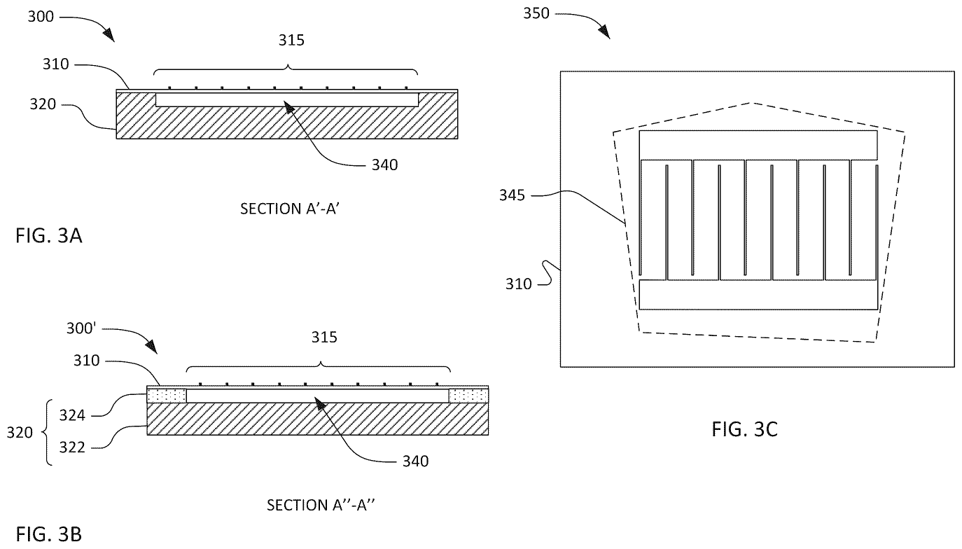

FIG. 3A and FIG. 3B show two alternative cross-sectional views along the section plane A-A defined in FIG. 1. In XBAR 300 of FIG. 3A, a piezoelectric plate 310 is attached to a substrate 320. A portion of the piezoelectric plate 310 forms a diaphragm 315 spanning a cavity 340 in the substrate. The cavity 340 does not fully penetrate the substrate 320. Fingers of an IDT are disposed on the diaphragm 315. The cavity 340 may be formed, for example, by etching the substrate 320 before attaching the piezoelectric plate 310. Alternatively, the cavity 340 may be formed by etching the substrate 320 with a selective etchant that reaches the substrate (or sacrificial etch material in a patterned substrate) through one or more openings (not shown) provided in the piezoelectric plate 310. In this case, the diaphragm 315 may be contiguous with the rest of the piezoelectric plate 310 around a large portion of a perimeter 345 of the cavity 340. For example, the diaphragm 315 may contiguous with the rest of the piezoelectric plate 310 around at least 50% of the perimeter 345 of the cavity 340. An intermediate layer (not shown), such as a dielectric bonding layer, may be present between the piezo electric plate 340 and the substrate 320.

In in XBAR 300′ of FIG. 3B, the substrate 320 includes a base 322 and an intermediate layer 324 disposed between the piezoelectric plate 310 and the base 322. For example, the base 322 may be silicon and the intermediate layer 324 may be silicon dioxide or silicon nitride or some other material. A portion of the piezoelectric plate 310 forms a diaphragm 315 spanning a cavity 340 in the intermediate layer 324. Fingers of an IDT are disposed on the diaphragm 315. The cavity 340 may be formed, for example, by etching the intermediate layer 324 before attaching the piezoelectric plate 310. Alternatively, the cavity 340 may be formed by etching the intermediate layer 324 with a selective etchant that reaches the substrate through one or more openings provided in the piezoelectric plate 310. In this case, the diaphragm 315 may be contiguous with the rest of the piezoelectric plate 310 around a large portion of a perimeter 345 of the cavity 340 (see FIG. 3C). For example, the diaphragm 315 may be contiguous with the rest of the piezoelectric plate 310 around at least 50% of the perimeter 345 of the cavity 340 as shown in FIG. 3C. Although not shown in FIG. 3B, a cavity formed in the intermediate layer 324 may extend into the base 322.

FIG. 3C is a schematic plan view of another XBAR 350. The XBAR 350 includes an IDT formed on a piezoelectric plate 310. A portion of the piezoelectric plate 310 forms a diaphragm spanning a cavity in a substrate. In this example, the perimeter 345 of the cavity has an irregular polygon shape such that none of the edges of the cavity are parallel, nor are they parallel to the conductors of the IDT. A cavity may have a different shape with straight or curved edges.

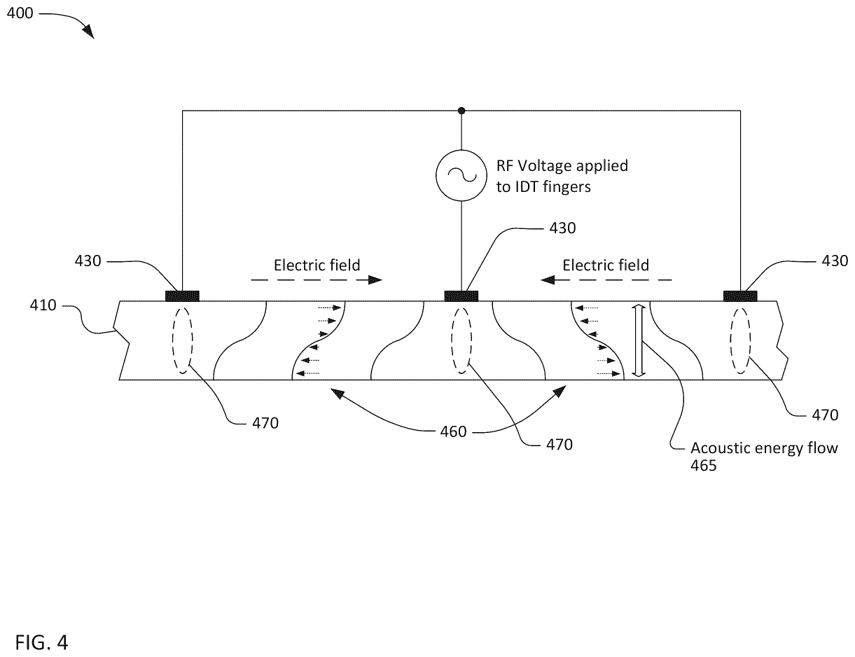

FIG. 4 is a graphical illustration of the primary acoustic mode of interest in an XBAR. FIG. 4 shows a small portion of an XBAR 400 including a piezoelectric plate 410 and three interleaved IDT fingers 430 which alternate in electrical polarity from finger to finger. An RF voltage is applied to the interleaved fingers 430. This voltage creates a time-varying electric field between the fingers. The direction of the electric field is predominantly lateral, or parallel to the surface of the piezoelectric plate 410, as indicated by the arrows labeled “electric field”. Due to the high dielectric constant of the piezoelectric plate, the RF electric energy is highly concentrated inside the plate relative to the air. The lateral electric field introduces shear deformation which couples strongly to a shear primary acoustic mode (at a resonance frequency defined by the acoustic cavity formed by the volume between the two surfaces of the piezoelectric plate) in the piezoelectric plate 410. In this context, “shear deformation” is defined as deformation in which parallel planes in a material remain predominantly parallel and maintain constant separation while translating (within their respective planes) relative to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and relative magnitude of atomic motion at the resonance frequency. The degree of atomic motion, as well as the thickness of the piezoelectric plate 410, have been greatly exaggerated for ease of visualization. While the atomic motions are predominantly lateral (i.e. horizontal as shown in FIG. 4), the direction of acoustic energy flow of the excited primary acoustic mode is substantially orthogonal to the surface of the piezoelectric plate, as indicated by the arrow 465.

Considering FIG. 4, there is essentially no RF electric field immediately under the IDT fingers 430, and thus acoustic modes are only minimally excited in the regions 470 under the fingers. There may be evanescent acoustic motions in these regions. Since acoustic vibrations are not excited under the IDT fingers 430, the acoustic energy coupled to the IDT fingers 430 is low (for example compared to the fingers of an IDT in a SAW resonator) for the primary acoustic mode, which minimizes viscous losses in the IDT fingers.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. Such devices are usually based on AlN thin films with the C axis of the AlN perpendicular to the surfaces of the film. The acoustic mode is compressive with atomic motions and the direction of acoustic energy flow in the thickness direction. In addition, the piezoelectric coupling for shear wave XBAR resonances can be high (>20%) compared to other acoustic resonators. High piezoelectric coupling enables the design and implementation of microwave and millimeter-wave filters with appreciable bandwidth.

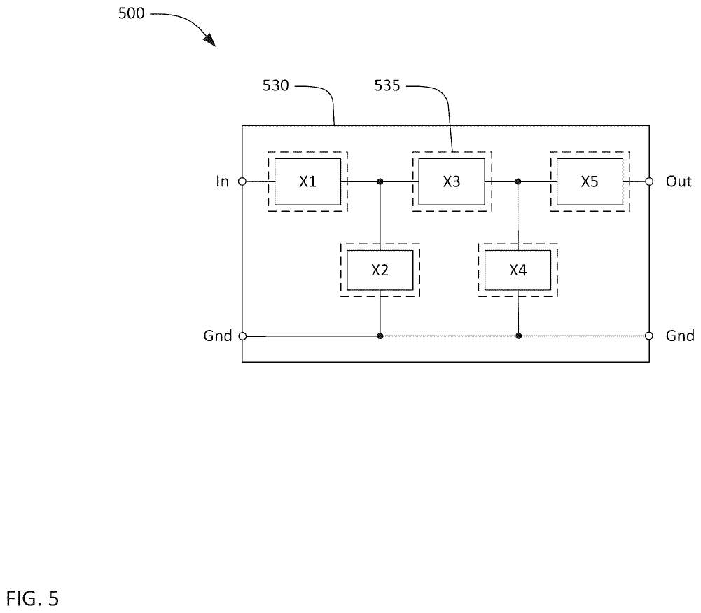

FIG. 5 is a schematic circuit diagram of a band-pass filter 500 using five XBARs X1-X5. The filter 500 may be, for example, a band n79 band-pass filter for use in a communication device. The filter 500 has a conventional ladder filter architecture including three series resonators X1, X3, X5 and two shunt resonators X2, X4. The three series resonators X1, X3, X5 are connected in series between a first port and a second port. In FIG. 5, the first and second ports are labeled “In” and “Out”, respectively. However, the filter 500 is bidirectional and either port may serve as the input or output of the filter. The two shunt resonators X2, X4 are connected from nodes between the series resonators to ground. All the shunt resonators and series resonators are XBARs.

The three series resonators X1, X3, X5 and the two shunt resonators X2, X4 of the filter 500 maybe formed on a single plate 530 of piezoelectric material bonded to a silicon substrate (not visible). Each resonator includes a respective IDT (not shown), with at least the fingers of the IDT disposed over a cavity in the substrate. In this and similar contexts, the term “respective” means “relating things each to each”, which is to say with a one-to-one correspondence. In FIG. 5, the cavities are illustrated schematically as the dashed rectangles (such as the rectangle 535). In this example, an IDT of each resonator is disposed over a respective cavity. In other filters, the IDTs of two or more resonators may be disposed over a common cavity. Resonators may also be cascaded into multiple IDTs which may be formed on multiple cavities.

Each of the resonators X1 to X5 has a resonance frequency and an anti-resonance frequency. In simplified terms, each resonator is effectively a short circuit at its resonance frequency and effectively an open circuit at its anti-resonance frequency. Each resonator X1 to X5 creates a “transmission zero”, where the transmission between the in and out ports of the filter is very low. Note that the transmission at a “transmission zero” is not actually zero due to energy leakage through parasitic components and other effects. The three series resonators X1, X3, X5 create transmission zeros at their respective anti-resonance frequencies (where each resonator is effectively an open circuit). The two shunt resonators X2, X4 create transmission zeros at their respective resonance frequencies (where each resonator is effectively a short circuit). In a typical band-pass filter using acoustic resonators, the anti-resonance frequencies of the series resonators create transmission zeros above the passband, and the resonance frequencies of the shunt resonators create transmission zeros below the passband.

A band-pass filter for use in a communications device, such as a cellular telephone, must meet a variety of requirements. First, a band-pass filter, by definition, must pass, or transmit with acceptable loss, a defined pass-band. Typically, a band-pass filter for use in a communications device must also stop, or substantially attenuate, one or more stop band(s). For example, a band n79 band-pass filter is typically required to pass the n79 frequency band from 4400 MHz to 5000 MHz and to stop the 5 GHz WiFi™ band and/or the n77 band from 3300 MHz to 4200 MHz. To meet these requirements, a filter using a ladder circuit would require series resonators with anti-resonance frequencies about or above 5100 MHz, and shunt resonators with resonance frequencies about or below 4300 MHz.

Another typical requirement on a band-pass filter for use in a communications device is the input and output impedances of the filter have to match, at least over the pass-band of the filter, the impedances of other elements of the communications device to which the filter is connected (e.g. a transmitter, receiver, and/or antenna) for maximum power transfer. Commonly, the input and output impedances of a band-pass filter are required to match a 50-ohm impedance within a tolerance that may be expressed, for example, as a maximum return loss or a maximum voltage standing wave ratio. When necessary, an impedance matching network comprising one or more reactive components can be used at the input and/or output of a band-pass filter. Such impedance matching networks add to the complexity, cost, and insertion loss of the filter and are thus undesirable. To match, without additional impedance matching components, a 50-Ohm impedance at a frequency of 5 GHZ, the capacitances of at least the shunt resonators in the band-pass filter need to be in a range of about 0.5 picofarads (pF) to about 1.5 picofarads.

The metal fingers of the IDTs provide the primary mechanism for removing heat from an XBAR resonator. Increasing the aperture of a resonator increases the length and the electrical and thermal resistance of each IDT finger. Further, for a given IDT capacitance, increasing the aperture reduces the number of fingers required in the IDT, which, in turn, proportionally increases the RF current flowing in each finger. All of these effects argue for using the smallest possible aperture in resonators for high-power filters.

Conversely, several factors argue for using a large aperture. First, the total area of an XBAR resonator includes the area of the IDT and the area of the bus bars. The area of the bus bars is generally proportional to the length of the IDT. For very small apertures, the area of the IDT bus bars may be larger than the area occupied by the interleaved IDT fingers. Further, some electrical and acoustic energy may be lost at the ends of the IDT fingers. These loss effects become more significant as IDT aperture is reduced and the total number of fingers is increased. These losses may be evident as a reduction in resonator Q-factor, particularly at the anti-resonance frequency, as IDT aperture is reduced.

As a compromise between conflicting objectives, resonator apertures will typically fall in the range from 20 μm and 60 μm for 5 GHz resonance frequency. Resonator aperture may scale inversely with frequency.

Communications devices operating in time-domain duplex (TDD) bands transmit and receive in the same frequency band. Both the transmit and receive signal paths pass through a common bandpass filter connected between an antenna and a transceiver. Communications devices operating in frequency-domain duplex (FDD) bands transmit and receive in different frequency bands. The transmit and receive signal paths pass through separate transmit and receive bandpass filters connected between an antenna and the transceiver. Filters for use in TDD bands or filters for use as transmit filters in FDD bands can be subjected to radio frequency input power levels of 30 dBm or greater and must avoid damage under power.

The required insertion loss of acoustic wave bandpass filters is usually not more than a few dB. Some portion of this lost power is return loss reflected back to the power source; the rest of the lost power is dissipated in the filter. Typical band-pass filters for LTE bands have surface areas of 1.0 to 2.0 square millimeters. Although the total power dissipation in a filter may be small, the power density can be high given the small surface area. Further, the primary loss mechanisms in an acoustic filter are resistive losses in the conductor patterns and acoustic losses in the IDT fingers and piezoelectric material. Thus, the power dissipation in an acoustic filter is concentrated in the acoustic resonators. To prevent excessive temperature increase in the acoustic resonators, the heat due to the power dissipation must be conducted away from the resonators through the filter package to the environment external to the filter.

In traditional acoustic filters, such as surface acoustic wave (SAW) filters and bulk acoustic wave (BAW) filters, the heat generated by power dissipation in the acoustic resonators is efficiently conducted through the filter substrate and the metal electrode patterns to the package. In an XBAR device, the resonators are disposed on thin piezoelectric diaphragms that are inefficient heat conductors. The large majority of the heat generated in an XBAR device must be removed from the resonator via the IDT fingers and associated conductor patterns.

The electric resistance of the IDT fingers can be reduced, and the thermal conductivity of the IDT fingers can be increased, by increasing the cross-sectional area of the fingers to the extent possible. As described in conjunction with FIG. 4, unlike SAW or BAW, for XBAR there is little coupling of the primary acoustic mode to the IDT fingers. Changing the width and/or thickness of the IDT fingers has minimal effect on the primary acoustic mode in an XBAR device. This is a very uncommon situation for an acoustic wave resonator. However, the IDT finger geometry does have a substantial effect on coupling to spurious acoustic modes, such as higher order shear modes and plate modes that travel laterally in the piezoelectric diaphragm.

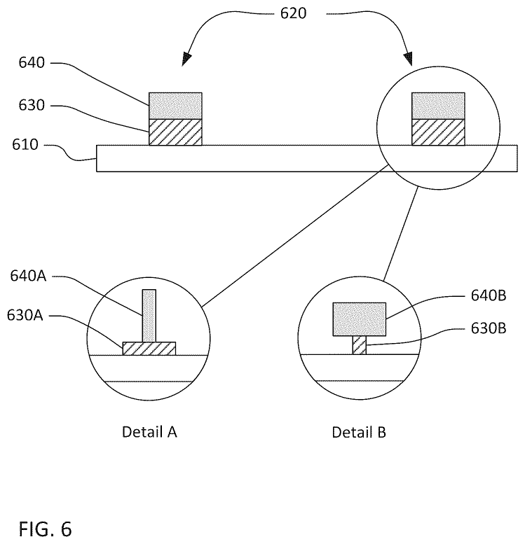

FIG. 6 is a cross-sectional view of a portion of an XBAR with two-layer IDT fingers. FIG. 6 shows a cross section though a portion of a piezoelectric diaphragm 610 and two IDT fingers 620. Each IDT finger 620 has two metal layers 630, 640. The lower (as shown in FIG. 6) layer 630 may be a metal with low acoustic impedance, such as aluminum, copper, molybdenum, silver, or titanium, e.g., a metal with low transverse acoustic impedance. Transverse acoustic impedance is the product of density and shear wave velocity. The lower layer 630 may be adjacent the diaphragm 610 or separated from the diaphragm 610 by a thin intermediate layer (not shown) used to improve adhesion between the diaphragm 610 and the lower layer 630. The upper layer 640 may be a metal with high thermal and electrical conductivity, such as aluminum, copper, or gold. The use of a metal with low acoustic impedance for the lower layer 630 closest to the diaphragm 610, where the acoustic stresses are greatest, reduces acoustic losses in the XBAR. Having two metal layers 630, 640 allows the designer to have additional design options to further improve performance of the XBAR.

Further, the two metal layers need not have the same thickness or cross-sectional shape, as shown in Detail A and Detail B of FIG. 6. In Detail A, the second metal layer 640A of each IDT finger has the form of a narrow rib on top of a thinner, wider first metal layer 630A. In Detail B, each IDT finger has a “T” cross section form by a narrow first metal layer 630B and a wider second metal layer 640B. The cross-section shapes of the first and second metal layers are not limited to rectangular as shown in FIG. 6. Other cross-sectional shapes including trapezoidal and triangular may be used and may be beneficial to minimize or control spurious acoustic modes.

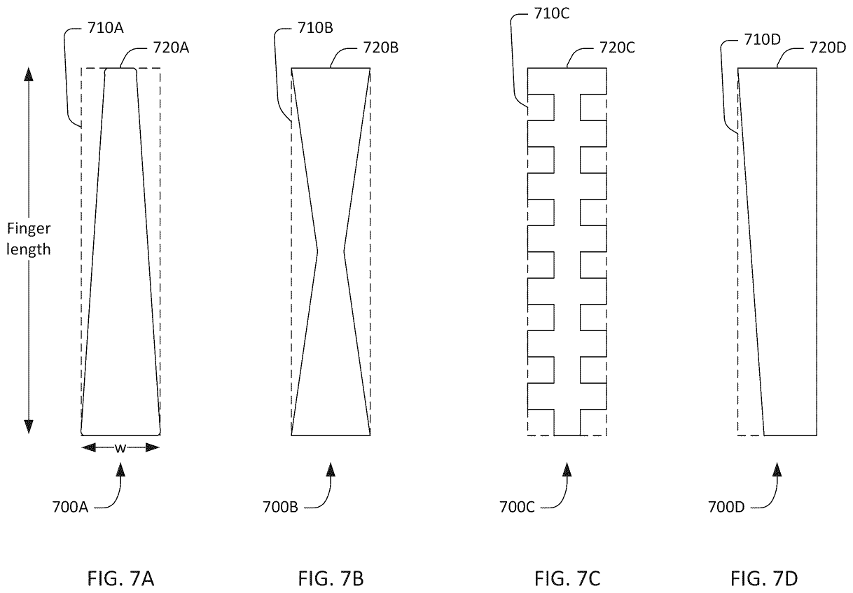

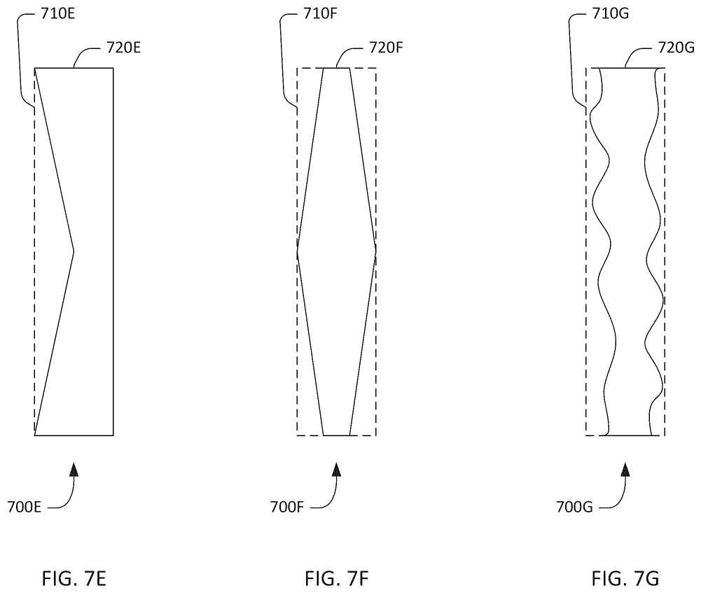

FIGS. 7A-G are plan views of exemplary two-layer XBAR IDT fingers with various shapes, which may reduce or modify spurious modes as compared with the XBARs with rectangular shapes. In each example, the lower layer adjacent the diaphragm is a rectangle (shown in dashed lines) with constant width. The upper layer has a significantly varying width along the length of the finger, preventing generation of resonances inside the finger at a single frequency and synchronous reflection of the propagating modes. The width w and finger length are identified in FIG. 7A.

In single layer fingers, some spurious modes can be reduced by careful adjustment of the electrode height and width, but only in limited frequency range that is not sufficient for a wide-band filter. There is no efficient way for mitigating the propagation of Lamb modes, which are usually high order harmonics (7th-13th, etc.) of S0 and A0.

In the two-layer fingers of FIGS. 7A-G, a constant width of the lower layer of the finger provides a uniform electric field between fingers and uniform excitation of the shear primary acoustic mode across the aperture. The variable width of the top layer of the finger along the length of the finger disrupts internal resonances inside the finger such that metal resonances will be mitigated. This will also reduce synchronous reflection and increase scattering of propagating modes, thus reducing their amplitude. An acoustic wave propagating in an electrode structure with constant periodicity tends to resonate at a frequency determined by the velocity of the wave and the periodicity of the structure. In XBAR devices, such resonances are undesired disturbances. By varying the width of the upper electrode layer, the resonance occurs at a different frequency in different locations along the finger, thus reducing a magnitude of the response.

The variation in width of the upper layer should be around half of the LN membrane thickness. The lower layer and the upper layer can be formed of the same or different materials. For example, the thickness of the lower layer could be in a range from 25% to 75% of the thickness of the diaphragm, and the thickness of the upper layer could be in a range from 25% to 75% of the thickness of the diaphragm. The upper layer and the lower layer can be formed of the same or different materials. The upper layer can cover the busbars to improve the heat transfer. In other examples, the fingers can have additional layers, such as three or four layers. A passivation layer can be formed on top of the fingers.

FIG. 7A is a plan view of a two-layer IDT finger 700A with an upper layer 720B extending along a length of the finger in a trapezoidal shape on a lower layer 710A with a constant width. The upper layer 720A tapers from a width about equal to the lower layer 710A at one end to a width about half of the lower layer 710A at the other end.

FIG. 7B is a plan view of a two-layer IDT finger 700B with an upper layer 720B extending along a length of the finger in an hourglass shape on a lower layer 710B of constant width. The upper layer 720B tapers from a width about equal to the lower layer 710B at one end, to a width about half of the lower layer 710B at a midpoint, to a width about equal to the lower layer 710B at the other end.

FIG. 7C is a plan view of a two-layer IDT finger 700C with an upper layer 720C extending along a length of the finger in a notched shape on a lower layer 710C of constant width. A width of the upper layer 720C is about equal to a width of the lower layer 710C at portions and equal to about half the width of the lower layer 710C at alternating portions with notches on opposing sides.

FIG. 7D is a plan view of a two-layer IDT finger 700D with an upper layer 720 extending along a length of the finger in another trapezoidal shape on a lower layer 710D of constant width. A width of the upper layer 720D tapers on one side so that a width of the upper layer 720D is about the width of the lower layer 710D at one end and is less than a width of the lower layer 710D at the other end.

FIG. 7E is a plan view of a two-layer IDT finger 700E with an upper layer 720E extending along a length of the finger in a half hourglass shape on a lower layer 710E of constant width. A width of the upper layer 720E tapers on one side so that a width of the upper layer 720E is about the width of the lower layer 710E at both ends and is less than a width of the lower layer 710D at a midpoint.

FIG. 7F is a plan view of a two-layer IDT finger 700F with an upper layer 720F extending along a length of the finger in an elongated hexagonal shape on a lower layer 710F of constant width. A width of the upper layer 720F tapers on both sides so that a width of the upper layer 720E is less than the width of the lower layer 710E at both ends and is about equal to a width of the lower layer 710D at a midpoint.

FIG. 7G is a plan view of a two-layer IDT finger 700G with an upper layer 720G extending along a length of the finger in an irregular shape on a lower layer 710G of constant width. A width of the upper layer varies along the length of the finger.

FIG. 7A through FIG. 7G are examples of a nearly unlimited number of possible upper electrode layer shapes. The upper layer can have any shape that varies along the length of each IDT finger. For example, the edges of the upper layer can be straight (as shown in FIG. 7A to FIG. 7G) or curved. The edges of the shapes of can also be a mix of curved and straight edges. The angles between straight edges can be greater or less than those shown in the figures. Two or more different upper layer shapes can be intermixed on the fingers of a single IDT and different upper layer shapes or combinations of shapes can be used on different acoustic resonators in a filter. For example, the shape of the upper layer can vary between different fingers of a single IDT or different IDTs in a device.

### Description of Methods

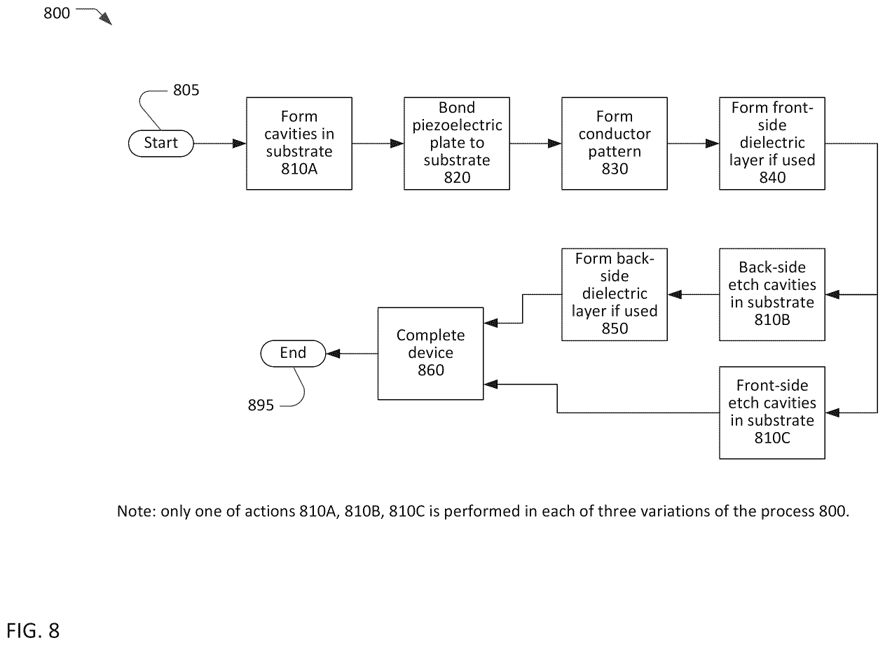

FIG. 8 is a simplified flow chart showing a process 800 for making an XBAR or a filter incorporating XBARs. The process 800 starts at 805 with a substrate and a plate of piezoelectric material and ends at 895 with a completed XBAR or filter. The flow chart of FIG. 8 includes only major process steps. Various conventional process steps (e.g. surface preparation, cleaning, inspection, baking, annealing, monitoring, testing, etc.) may be performed before, between, after, and during the steps shown in FIG. 8.

The flow chart of FIG. 8 captures three variations of the process 800 for making an XBAR which differ in when and how cavities are formed in the substrate. The cavities may be formed at steps 810A, 810B, or 810C. Only one of these steps is performed in each of the three variations of the process 800.

The piezoelectric plate may be, for example, rotated Z-cut lithium niobate. The Euler angles of the piezoelectric plate are 0, β, 90°, where β is in the range from −15° to +5°. Preferably, β may be in the range from −11° to −5° to maximize electromechanical coupling. β may be in the range from −10° to −7.5° to maximize Q-factor at the resonance frequency. The substrate may preferably be silicon. The substrate may be some other material that allows formation of deep cavities by etching or other processing, or has other tradeoffs in mechanical performance or cost.

In one variation of the process 800, one or more cavities are formed in the substrate at 810A, before the piezoelectric plate is bonded to the substrate at 820. A separate cavity may be formed for each resonator in a filter device. The one or more cavities may be formed using conventional photolithographic and etching techniques. Typically, the cavities formed at 810A will not penetrate through the substrate.

At 820, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. When a dielectric material is sandwiched between the piezoelectric plate and the substrate during bonding, the dielectric material may subsequently be left in place or removed. One or both mating surfaces may be activated using, for example, a plasma process. The mating surfaces may then be pressed together with considerable force to establish molecular bonds between the piezoelectric plate and the substrate or intermediate material layers.

A lower conductor pattern, including the lower layers of the IDTs of each XBAR, is formed at 830 by depositing and patterning one or more lower conductor layer on the front side of the piezoelectric plate. The lower conductor layer may be, for example, aluminum, an aluminum alloy, copper, a copper alloy, or some other conductive metal. Optionally, one or more layers of other materials may be disposed below (i.e. between the conductor layer and the piezoelectric plate) and/or on top of the conductor layer. For example, a thin film of titanium, chrome, or other metal may be used to improve the adhesion between the lower conductor layer and the piezoelectric plate.

The lower conductor pattern may be formed at 830 by depositing the lower conductor layer and, optionally, one or more other metal layers in sequence over the surface of the piezoelectric plate. The excess metal may then be removed by etching through patterned photoresist. The lower conductor layer can be etched, for example, by plasma etching, reactive ion etching, wet chemical etching, and other etching techniques.

Alternatively, the lower conductor pattern may be formed at 830 using a lift-off process. Photoresist may be deposited over the piezoelectric plate, and patterned to define the conductor pattern. The lower conductor layer and, optionally, one or more other layers may be deposited in sequence over the surface of the piezoelectric plate. The photoresist may then be removed, which removes the excess material, leaving the lower conductor pattern.

An upper conductor pattern, including the upper layers of the IDTs of each XBAR, is formed at 835 by depositing and patterning one or more upper conductor layer on the front side of the piezoelectric plate. The upper conductor pattern may be formed using the same techniques described for the lower conductor pattern with a different mask.

When the device has additional conductor layers, the layers may be deposited and patterned separately. In particular, different patterning processes (i.e., etching or lift-off) may be used on different layers and different masks are required where two or more layers have different widths or shapes.

At 840, a front-side dielectric layer may be formed by depositing one or more layers of dielectric material on the front side of the piezoelectric plate. The one or more dielectric layers may be deposited using a conventional deposition technique such as sputtering, evaporation, or chemical vapor deposition. The one or more dielectric layers may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate.

In a second variation of the process 800, one or more cavities are formed in the back side of the substrate at 810B. A separate cavity may be formed for each resonator in a filter device. The one or more cavities may be formed using an anisotropic or orientation-dependent dry or wet etch to open holes through the back side of the substrate to the piezoelectric plate. In this case, the resulting resonator devices will have a cross-section as shown in FIG. 1.

In the second variation of the process 800, a back-side dielectric layer may be formed at 850. In the case where the cavities are formed at 810B as holes through the substrate, the back-side dielectric layer may be deposited through the cavities using a conventional deposition technique such as sputtering, evaporation, or chemical vapor deposition.

In a third variation of the process 800, one or more cavities in the form of recesses in the substrate may be formed at 810C by etching the substrate using an etchant introduced through openings in the piezoelectric plate. A separate cavity may be formed for each resonator in a filter device.

In all variations of the process 800, the filter device is completed at 860. Actions that may occur at 860 include depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 860 is to tune the resonant frequencies of the resonators within the device by adding or removing metal or dielectric material from the front side of the device. After the filter device is completed, the process ends at 895.

### Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator device comprising:
a piezoelectric layer; and
an interdigital transducer (IDT) at a surface of the piezoelectric layer, the IDT comprising interleaved fingers,
wherein at least one interleaved finger of the interleaved fingers comprises a first layer and a second layer over the first layer, wherein the first layer is between the piezoelectric layer and the second layer,
wherein a shape of the second layer varies with respect to at least one other interleaved finger of the interleaved fingers, and
wherein a thickness of the first layer is less than a thickness of the second layer.

2. The acoustic resonator device of claim 1, wherein the piezoelectric layer and the IDT are configured such that a radio frequency signal applied to the IDT excites a primary shear acoustic mode in the piezoelectric layer where a direction of an electric field of the primary shear acoustic mode is predominantly lateral in the piezoelectric layer, and wherein the primary shear acoustic mode propagates substantially orthogonal to direction of the electric field and substantially orthogonal to the surface of the piezoelectric layer.

3. The acoustic resonator device of claim 1, wherein a shape of the first layer of the at least one interleaved finger is non-rectangular.

4. The acoustic resonator device of claim 1, wherein the shape of the second layer of a first interleaved finger is non-rectangular.

5. The acoustic resonator device of claim 1, wherein a width of the second layer varies along a length of the at least one interleaved finger.

6. The acoustic resonator device of claim 1, wherein a width of the second layer increases along a first portion of the second layer and decreases along a second portion of the second layer.

7. The acoustic resonator device of claim 1, wherein an aperture of the acoustic resonator is defined as a distance of overlap of at least two interleaved fingers of the IDT, wherein the resonator aperture is between 20 micrometers (μm) and 60 μm.

8. The acoustic resonator device of claim 1, wherein a width of the second layer along a length of the at least one interleaved finger is less than a width of the first layer.

9. The acoustic resonator device of claim 1, further comprising an adhesion layer between the first layer and the piezoelectric layer.

10. A filter device comprising:
a plurality of bulk acoustic resonators, each comprising:
a piezoelectric layer; and
a conductor pattern at a surface of the piezoelectric layer, the conductor pattern including an interdigital transducer (IDT) having interleaved fingers,
wherein at least one interleaved finger of the interleaved fingers comprises a first layer either adjacent the piezoelectric layer, or separated from the piezoelectric layer by an intermediate layer, and a second layer over the first layer,
wherein, for at least one of the plurality of bulk acoustic resonators, a shape of the second layer of a first interleaved finger of the interleaved fingers is different from a shape of the second layer of a second interleaved finger of the interleaved fingers, and
wherein, for at least one of the plurality of acoustic resonators, a thickness of the first layer of the at least one interleaved finger of the interleaved fingers is less than a thickness of the second layer of the at least one interleaved finger of the interleaved fingers.

11. The filter device of claim 10, wherein the piezoelectric layer and IDT of at least one of the plurality of bulk acoustic resonators are configured such that respective radio frequency signals applied to the IDT excites respective shear primary acoustic modes in the piezoelectric layer, wherein a direction of an electric field of the primary shear acoustic mode is predominantly lateral in the piezoelectric layer, and wherein the primary shear acoustic mode propagates substantially orthogonal to direction of the electric field and substantially orthogonal to the surface of the piezoelectric layer.

12. The filter device of claim 10, wherein, for at least one of the plurality of acoustic resonators, a width of the second layer varies along a length of the at least one interleaved finger.

13. The filter device of claim 10, wherein, for at least one of the plurality of bulk acoustic resonators, a pitch is a distance between two adjacent fingers extending from different busbars of the conductor pattern, wherein the pitch is between 2 and 20 times the thickness of the piezoelectric layer.

14. The filter device of claim 10, wherein, for at least one of the plurality of bulk acoustic resonators, the shape of the second layer of a first interleaved finger is non-rectangular.

15. The filter device of claim 10, wherein, for at least one of the plurality of bulk acoustic resonators, a width of the second layer of the at least one interleaved finger increases along a first portion of the second layer and decreases along a second portion of the second layer.

16. The acoustic resonator device of claim 1, wherein, for at least one of the plurality of bulk acoustic resonators, an aperture is defined as a distance of overlap of at least two interleaved fingers of the IDT, wherein the aperture is 20 micrometers (μm) and 60 μm.

17. The filter device of claim 10, wherein, for at least one of the plurality of acoustic resonators, a width of the second layer along a length of the at least one interleaved finger is less than or equal to a width of the first layer.

18. The filter device of claim 10, wherein the shape of the second layer is different than a shape of the first layer.

19. The filter device of claim 10, wherein the second layer has a varying width along a length of the at least one interleaved finger, such that the second layer is configured to prevent generation of resonances inside the at least one interleaved finger at a single frequency and synchronous reflection of the propagating modes.

20. An acoustic resonator device comprising:
a piezoelectric layer; and
an interdigital transducer (IDT) at a surface of the piezoelectric layer, the IDT comprising a pair of busbars with interleaved fingers extending therefrom, respectively,
wherein at least one interleaved finger of the interleaved fingers comprises a first layer on the piezoelectric layer and a second layer over the first layer,
wherein a width of the second layer of the at least one interleaved finger varies as the at least one interleaved finger extends from the respective busbar of the pair of busbars,
wherein a thickness of the first layer is less than a thickness of the second layer, and
wherein a pitch is a distance between two adjacent fingers extending from different busbars of the conductor pattern, wherein the pitch is between 2 and 20 times the thickness of the piezoelectric layer.
